(19) United States
(12) Patent Application Publication
(10) Pub. No.: US 2026/0357411 A1
(43) Pub. Date: Nov. 12, 2026

(54) APPARATUS AND SYSTEMS FOR ALKALI METAL DEPOSITION

(71) Applicant: Elevated Materials Germany GmbH, Alzenau (DE)

(72) Inventors: PrasannaKalleshwara Buddappa Ramachandrappa, Santa Clara, CA (US); Sambhu Nath Kundu, Santa Clara, CA (US); Sumedh Dattatraya Acharya, Bangalore (IN); Sandip Sambhajirao Desai, Bangalore (IN); Ramesh Haveri Murigeppa, Bangalore (IN); Devendra Chandrashekaraiah, Bangalore (IN); Suresh Manikkoth Kollarath, Bangalore (IN); Visweswaren Sivaramakrishnan, Santa Clara, CA (US)

(21) Appl. No.: 19/487,380

(22) PCT Filed: May 6, 2024
(86) PCT No.: PCT/US2024/028039

§ 371 Date: Nov. 24, 2025

Related U.S. Application Data
(60) Provisional application No. 63/469,264, filed on May 26, 2023.

(51) Int. Cl. C23C 14/24; C23C 14/14; H01M 4/04

(52) U.S. Cl. CPC C23C 14/243; C23C 14/14; H01M 4/0421

(57) ABSTRACT

Embodiments of the present disclosure generally relate to apparatus and systems for alkali metal deposition. In an embodiment, an evaporation assembly includes a first heater region comprising a plurality of first heaters; an evaporator body, at least a portion of the evaporator body positioned within the first heater region, wherein the evaporator body comprises a top surface having a plurality of linear arrays of nozzles; and a second heater region comprising one or more second heaters. The evaporation assembly further includes a crucible positioned within the second heater region, the crucible comprising a crucible body fluidly coupled with the evaporator body, wherein the crucible body: defines an interior region for holding the material to be evaporated, has an opening through which the evaporated material can escape, and has a length dimension and a width dimension defining an evaporation surface area.

### FIELD

Embodiments of the present disclosure generally relate to apparatus and systems for alkali metal deposition.

### BACKGROUND

Tools for forming electrode structures include roll-to-roll (reel-to-reel) systems for transporting a substrate through various processing chambers including processing chambers to deposit alkali metal films on the substrate. Such alkali metal depositions are performed under vacuum. Within the vacuum chamber, an alkali metal feedstock is fed to a crucible disposed within an evaporator. The evaporator is placed at some vertical distance from the substrate level. The crucible is heated to achieve alkali metal evaporation and deposition onto the substrate. Currently, the run length—a period between which deposition occurs without any break in vacuum—is limited due to the volume of the evaporator (and crucible) and consequently the amount of alkali metal in an evaporator. As the amount of alkali metal reduces during evaporation, additional amounts of lithium are supplied to the evaporator in situ and under vacuum. However, the transfer of this new alkali metal to the heated evaporator causes additional problems due to the difference in temperature between the lithium in the evaporator and the lithium being fed to the evaporator. Conventional technologies have not addressed these and other issues.

There is a need for new and improved apparatus and systems for alkali metal deposition.

### SUMMARY

Embodiments of the present disclosure generally relate to apparatus and systems for alkali metal deposition.

In an embodiment, an evaporation assembly for alkali metal deposition is provided. The evaporation assembly includes a first heater region comprising a plurality of first heaters, an evaporator body, at least a portion of the evaporator body positioned within the first heater region, wherein: the evaporator body comprises a top surface having a plurality of linear arrays of nozzles. The evaporation assembly further includes a second heater region comprising one or more second heaters; and a crucible positioned within the second heater region, the crucible comprising a crucible body fluidly coupled with the evaporator body, wherein: the crucible body defines an interior region for holding the material to be evaporated; the crucible body has an opening through which the evaporated material can escape; and the crucible body has a length dimension and a width dimension defining an evaporation surface area.

Implementations may include one or more of the following. Each nozzle of the evaporation assembly can have an opening defined by a diameter, a total area of the openings defines a nozzle opening surface area, and/or the evaporation surface area of the crucible body is greater than the nozzle opening surface area. The evaporator body can further include a bottom surface which corresponds with the opening in the crucible body. The evaporator body can further include a first pair of opposing sidewalls extending downward from the top surface, the first pair of opposing sidewalls defining a length dimension of the evaporator body and/or the evaporator body can further include a second pair of opposing sidewalls extending downward from the top surface, the second pair of opposing sidewalls defining a width dimension of the evaporator body. The plurality of first heaters of the first heater region can extend the length dimension of the evaporator body. The first heater region can further include a first conductive member positioned between a first heater of the first plurality of heaters and a first sidewall of the first pair of opposing sidewalls; and/or a second conductive member positioned between a second heater of the first plurality of heaters and a second sidewall of the first pair of opposing sidewalls. The third heater of the first plurality of heaters can be positioned between the first and second heaters of the first plurality of heaters. The plurality of first heaters are tubular heaters; and/or the one or more second heaters are tubular heaters. The evaporation assembly can further include an alkali metal delivery line. The alkali metal delivery line can include: a first section positioned exterior to the evaporation assembly; a second section positioned in an interior region of the evaporation assembly, the second section traversing the interior of the evaporator body and the crucible body; a third section positioned in an interior region of the evaporation assembly and below the opening of the crucible body; and/or a plurality of openings through which alkali metal enters the crucible. The crucible of the evaporation assembly can be free of compartments and/or the evaporation assembly can be free of an external heater that radiatively heats the crucible. The evaporation assembly can further include a heated delivery line, the heated delivery line coupled to the interior region of the crucible body, the heated delivery line for supplying alkali metal to be deposited to the crucible body.

In another embodiment, an evaporation assembly for alkali metal deposition is provided. The evaporation assembly includes a first heater region comprising a plurality of first heaters; and a second heater region comprising one or more second heaters. The evaporation assembly further includes an evaporator body, at least a portion of the evaporator body positioned within the first heater region and within the second heater region, wherein: the evaporator body comprises: a top surface having a plurality of linear arrays of nozzles; a first pair of opposing sidewalls extending outward from the top surface, the first pair of opposing sidewalls defining a length dimension of the evaporator body; and a second pair of opposing sidewalls extending outward from the top surface, the second pair of opposing sidewalls defining a width dimension of the evaporator body; and the plurality of first heaters of the first heater region extend the length dimension of the evaporator body. The evaporation assembly further includes a third heater region comprising one or more third heaters; and a crucible positioned within the third heater region, the crucible further positioned outside of the first heater region and the second heater region, the crucible comprising a crucible body fluidly coupled with the evaporator body, wherein: the crucible body defines an interior region for holding the material to be evaporated; the crucible body has an opening through which the evaporated material can escape; and the crucible body has a length dimension and a width dimension defining an evaporation surface area; and wherein the second heater region is positioned above the opening of the crucible body.

Implementations may include one or more of the following. The first heater region can further include a first conductive member positioned between a first heater of the first plurality of heaters and a first sidewall of the first pair of opposing sidewalls; and/or a second conductive member positioned between a second heater of the first plurality of heaters and a second sidewall of the first pair of opposing sidewalls. The one or more second heaters of the second heater region can extend the length dimension of the evaporator body. Each nozzle can have an opening defined by a diameter, a total area of the openings defines a nozzle opening surface area, and/or the evaporation surface area of the crucible body can be greater than the nozzle opening surface area. The evaporator body can further include a bottom surface which corresponds with the opening in the crucible body; and/or a side surface which corresponds with a side surface of the crucible. The evaporation assembly can further include an alkali metal delivery line. The alkali metal delivery line can include: a first section positioned exterior to the evaporation assembly; a second section positioned in an interior region of the evaporation assembly, the second section traversing the interior of the evaporator body and the crucible body; a third section positioned in an interior region of the evaporation assembly and below the opening of the crucible body; and/or a plurality of openings through which alkali metal enters the crucible. The crucible of the evaporation assembly can be free of compartments and/or the evaporation assembly can be free of an external heater that radiatively heats the crucible. The evaporation assembly can further include a heated delivery line, the heated delivery line coupled to the interior region of the crucible body, the heated delivery line for supplying alkali metal to be deposited to the crucible body.

In another embodiment, a processing chamber for depositing alkali metal is provided. The processing chamber includes a coating drum; and a plurality of evaporation assemblies described herein, the plurality of evaporation assemblies radially disposed about the coating drum.

Implementations may include one or more of the following. A first evaporation assembly of the plurality of evaporation assemblies can have a first angle of inclination; and/or a second evaporation assembly of the plurality of evaporation assemblies can have a second angle of inclination that is different from the first angle of inclination. The second evaporation assembly can be a same or different evaporation assembly as the first evaporation assembly. The first angle of inclination can be from about 20 degrees to about 25 degrees; and/or the second angle of inclination is from about 65 degrees to about 70 degrees.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, and may admit to other equally effective embodiments.

FIG. 1A illustrates a schematic front view of an example processing chamber having an evaporation assembly according to one or more embodiments of the present disclosure.

FIG. 1B illustrates a schematic front view of a portion of an example processing chamber having an evaporation assembly according to one or more embodiments of the present disclosure.

FIG. 2A shows a first perspective view of an example evaporation assembly, for example, a thermal evaporator, according to at least one embodiment of the present disclosure.

FIG. 2B shows a cross-sectional side view of the example evaporation assembly of FIG. 2A according to at least one embodiment of the present disclosure.

FIG. 2C shows a second cross-sectional perspective view of the example evaporation assembly of FIG. 2A with a side removed according to at least one embodiment of the present disclosure.

FIG. 2D shows a second side view of the example evaporation assembly of FIG. 2A, with a side removed, according to at least one embodiment of the present disclosure.

FIG. 3A shows a perspective view of an example evaporation assembly, for example, a thermal evaporator, according to at least one embodiment of the present disclosure.

FIG. 3B shows a side view of the example evaporation assembly of FIG. 3A according to at least one embodiment of the present disclosure.

FIG. 4 shows an example nozzle assembly according to at least one embodiment of the present disclosure.

FIG. 5A shows an example hot shield assembly according to at least one embodiment of the present disclosure.

FIG. 5B shows an example mounting mechanism of the example hot shield assembly of FIG. 5A according to at least one embodiment of the present disclosure.

FIG. 5C shows the example hot shield assembly of FIG. 5A positioned between a frame and a coating drum of a processing chamber according to at least one embodiment of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Reference will now be made in detail to the various implementations of the present disclosure, one or more examples of which are illustrated in the figures. Within the following description of the drawings, the same reference numbers refer to the same components. Generally, only the differences with respect to individual implementations are described. Each example is provided by way of explanation of the present disclosure and is not meant as a limitation of the present disclosure. Further, features illustrated or described as part of one implementation can be used on or in conjunction with other implementations to yield yet a further implementation. It is intended that the description includes such modifications and variations.

Many of the details, dimensions, angles and other features shown in the Figures are merely illustrative of particular implementations. Accordingly, other implementations can have other details, components, dimensions, angles and features without departing from the spirit or scope of the present disclosure. In addition, further implementations of the disclosure can be practiced without several of the details described below.

According to some implementations, evaporation processes and evaporation apparatus for layer deposition on substrates, for example on flexible substrates, are provided. Thus, flexible substrates can be considered to include among other things films, foils, webs, strips of plastic material, metal, or other materials. Typically, the terms “web,” “foil,” “strip,” “substrate” and the like are used synonymously. According to some implementations, components for evaporation processes, apparatuses for evaporation processes and evaporation processes according to implementations described herein can be provided for the above-described flexible substrates. However, they can also be provided in conjunction with non-flexible substrates such as glass substrates or the like, which are subject to the reactive deposition process from evaporation sources.

Vacuum web coating for anode pre-lithiation and solid metal anode protection involves thick (three to twenty micron) metallic (e.g., lithium) deposition on double-side-coated and calendered alloy-type graphite anodes and current collectors, for example, six micron or thicker copper foil, nickel foil, or metallized plastic web. One technique for deposition is thermal evaporation. Thermal evaporation readily takes place when a source material is heated in an open crucible within a vacuum chamber when a temperature is reached such that there is a sufficient vapor flux from the source for condensation on a cooler substrate. The source material can be heated indirectly by heating the crucible, or directly by a high current electron beam directed into the source material confined by the crucible.

Thermal evaporators described herein can include a crucible design, which provides an increased surface area for evaporation of the material to be deposited relative to conventional designs. The increased surface area for evaporation means that more vapor of the evaporated material can be produced, which increases pressure inside the evaporator body leading to increased flow of the evaporated material out of the nozzles. The crucible can be attached to an evaporator body of the thermal evaporator. The crucible can be integrated within the evaporator body. The evaporator body can include a plurality of longitudinal grooves, which increase the surface area of the evaporator body.

In one implementation which can be combined with other implementations, an evaporation assembly is provided. The evaporation assembly includes a crucible for holding a material to be evaporated. The crucible includes a rectangular body defining an interior region for holding the material to be evaporated. The rectangular body includes an opening through which the evaporated material can escape. The rectangular body has a length dimension and a width dimension that define an evaporation surface area. An evaporator body is fluidly coupled with the rectangular body.

The evaporator body has a top surface including a plurality of linear arrays of nozzles. Each nozzle has an opening defined by a diameter and a total area of the nozzle openings defines a nozzle opening surface area and the evaporation surface area is greater than the nozzle opening surface area. The nozzle opening surface areas can be calculated using the formula n*π² where “n” represents the total number of nozzles and “r” represents the radius of the nozzle opening. The evaporation surface area of the crucible can be calculated by multiplying the length dimension “I” of the crucible times the width of the crucible “w”.

The use of headings is for purposes of convenience only and does not limit the scope of the present disclosure. Embodiments described herein can be combined with other embodiments.

### Processing Chamber

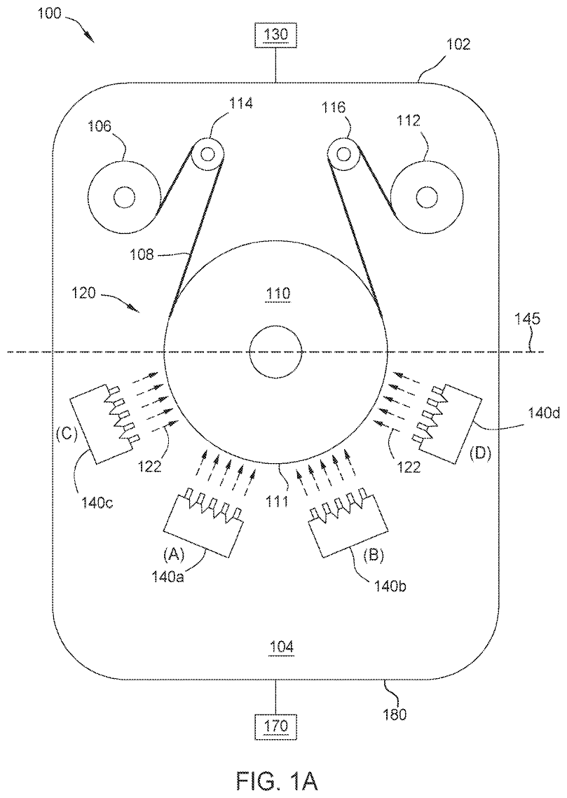

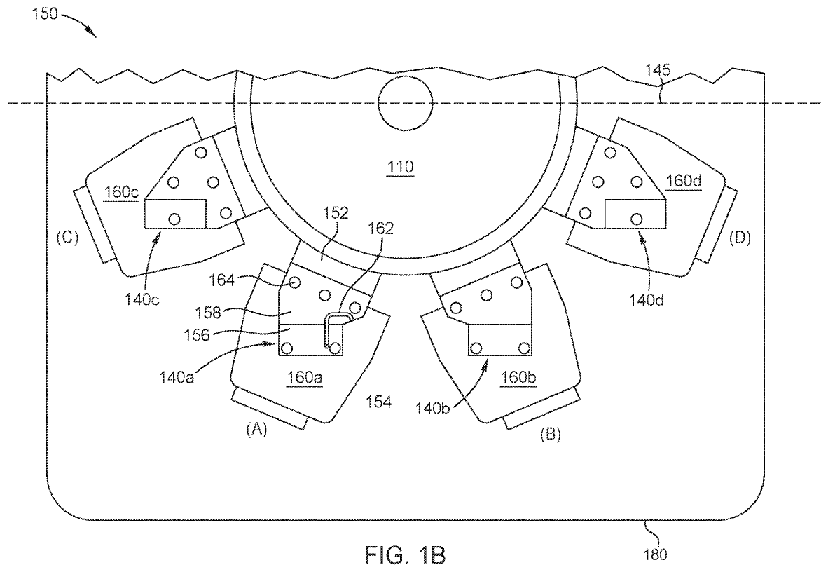

FIG. 1A illustrates a schematic front view of a processing chamber 100 including one or more evaporation assemblies 140a-140d (collectively 140), for example, thermal evaporators, and a coating drum 110, according to one or more implementations of the present disclosure. The processing chamber 100 can be a roll-to-roll system adapted for depositing coatings on web materials, for example, for depositing metal containing film stacks according to the implementations described herein. As shown, a first evaporation assembly 140a is located at a first position (A), a second evaporation assembly 140b is located at a second position (B), a third evaporation assembly 140c is located at a third position (C), and a fourth evaporation assembly 140d is located at a fourth position (D). Evaporation assemblies 140 described herein can be made of any suitable material such as stainless steel, graphite, boron nitride, pyrolytic boron nitride, molybdenum, tungsten, titanium, tantalum, nickel, alloys thereof, or combinations thereof.

The angle of inclination of the first evaporation assembly 140a and the second evaporation assembly 140b on a coating drum 110 of the processing chamber 100 can be from about 20 degrees to about 25 degrees, such as from about 21 degrees to about 24 degrees, such as from about 22 degrees to about 23 degrees, such as about 22.5 degrees, though other angles of inclination are contemplated. Any of the foregoing numbers can be used singly to describe an open-ended range or in combination to describe a close-ended range. The angle of inclination is with respect to the bottom plate 180 of the processing chamber 100, 150 (the horizontal plane of the page indicated by dashed line 145).

The angle of inclination of the third evaporation assembly 140c and the fourth evaporation assembly 140d on the coating drum 110 of the processing chamber 100 can be from about 65 degrees to about 70 degrees, such as from about 66 degrees to about 69 degrees, such as from about 67 degrees to about 68 degrees, such as about 67.5 degrees, though other angles of inclination are contemplated. Any of the foregoing numbers can be used singly to describe an open-ended range or in combination to describe a close-ended range. The angle of inclination is with respect to the bottom plate 180 of the processing chamber 100, 150 (the horizontal plane of the page indicated by the dashed line 145).

In one example, the processing chamber 100 can be used for depositing metals or metal alloys. For example, the processing chamber 100 and evaporation assemblies 140 can be used for depositing metals or metal alloys. Examples of metal and metal alloys include but are not limited to alkali metals (e.g., lithium or sodium), selenium, magnesium, zinc, cadmium, aluminum, gallium, indium, thallium, tin, lead, antimony, bismuth, and tellurium, alkali earth metals, silver, or a combination thereof. These metals or metal alloys can be used for manufacturing energy storage devices, and particularly for film stacks for lithium-containing anode structures. Although embodiments are described herein with reference to alkali metals, it should be understood that other metals and metal alloys can be used with embodiments of the present disclosure such as those described above.

The processing chamber 100 includes a chamber body 102 that defines a common processing environment 104 in which some or all of the processing actions for depositing coatings on web materials can be performed. In one example, the common processing environment 104 is operable as a vacuum environment. In another example, the common processing environment 104 is operable as an inert gas environment. In some examples, the common processing environment 104 can be maintained at a process pressure of 1×10⁻³ mbar or below, for example, 1×10⁻⁴ mbar or below.

The processing chamber 100 is constituted as a roll-to-roll system including an unwinding reel 106 for supplying a continuous flexible substrate 108 or web, the coating drum 110 over which the continuous flexible substrate 108 is processed, and a winding reel 112 for collecting the continuous flexible substrate 108 after processing. The coating drum 110 includes a deposition surface 111 over which the continuous flexible substrate 108 travels while material is deposited onto the continuous flexible substrate 108. The processing chamber 100 can further include one or more auxiliary transfer reels 114, 116 positioned between the unwinding reel 106, the coating drum 110, and the winding reel 112. According to one aspect, at least one of the one or more auxiliary transfer reels 114, 116, the unwinding reel 106, the coating drum 110, and the winding reel 112, can be driven and rotated by a motor. In one example, the motor is a stepper motor. Although the unwinding reel 106, the coating drum 110, and the winding reel 112 are shown as positioned in the common processing environment 104, it should be understood that the unwinding reel 106 and the winding reel 112 can be positioned in separate chambers or modules, for example, at least one of the unwinding reel 106 can be positioned in an unwinding module, the coating drum 110 can be positioned in a processing module, and the winding reel 112 can be positioned in an unwinding module.

The unwinding reel 106, the coating drum 110, and the winding reel 112 can be individually temperature controlled. For example, the unwinding reel 106, the coating drum 110, and the winding reel 112 can be individually heated using an internal heat source positioned within each reel or an external heat source.

In one implementation, which can be combined with other implementations, the one or more evaporation assemblies 140, for example, thermal evaporators, can be removably coupled with an evaporation shield (not shown). In another implementation, which can be combined with other implementations, the one or more evaporation assemblies 140 can be spaced apart from the coating drum 110. The one or more thermal evaporation assemblies 140 are positioned to deliver evaporated material onto the continuous flexible substrate 108 as the continuous flexible substrate 108 travels over the deposition surface 111 of the coating drum 110.

A deposition volume 120 is defined in between the one or more thermal evaporation assemblies 140 and the deposition surface 111 of the coating drum 110. In some implementations, the deposition volume 120 provides an isolated processing within the common processing environment 104 of the chamber body 102. The deposition volume 120 can be minimized and defined to conform to a web, for example, the continuous flexible substrate 108 that is wound on a cylindrical cooling drum, for example, the coating drum 110, a planar cooling plate, or in a free span orientation.

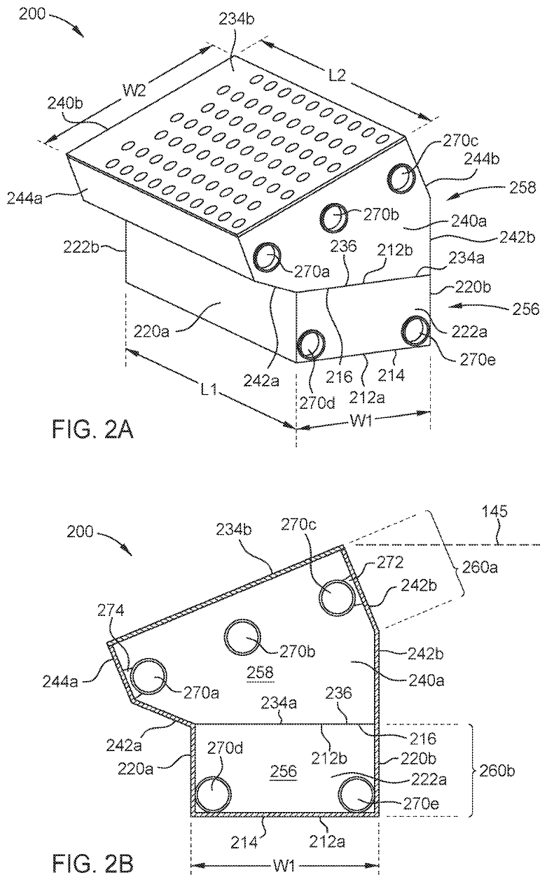

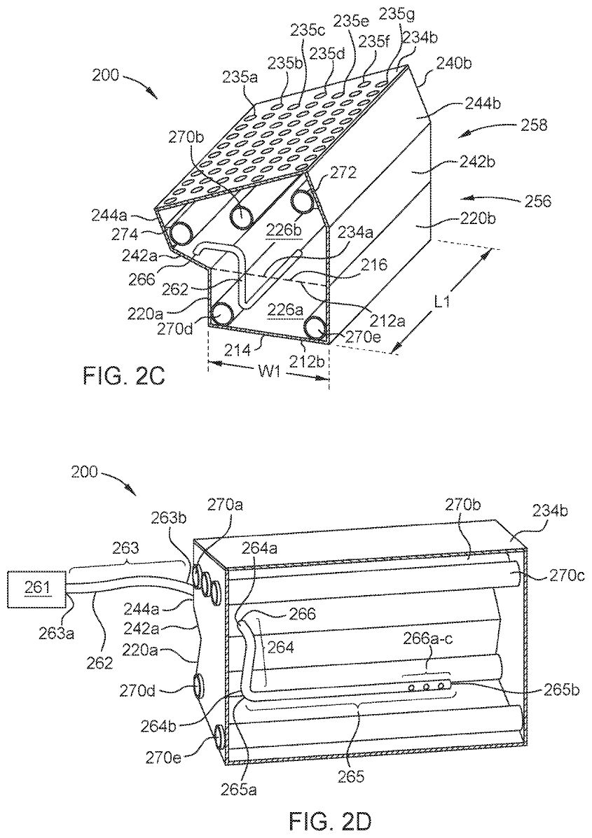

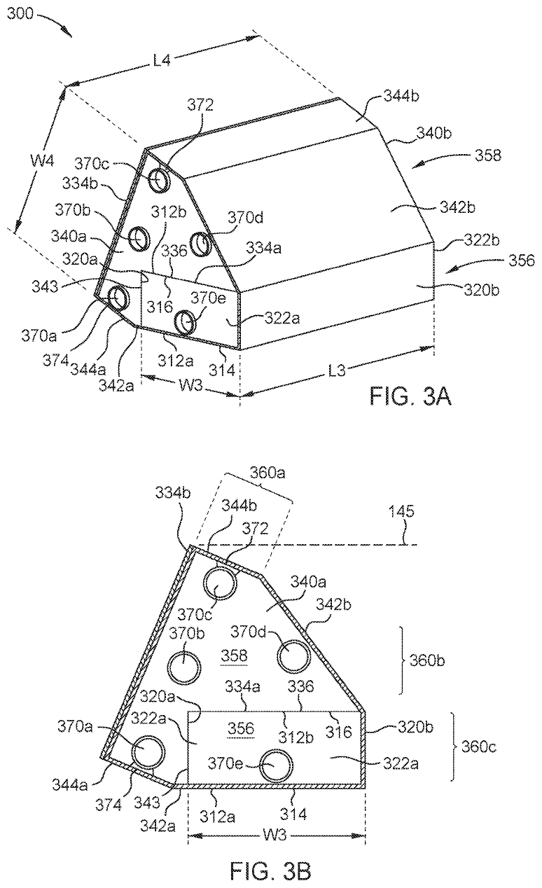

The one or more evaporation assemblies 140 will be described in greater detail below with reference to FIGS. 2 and 3. The one or more evaporation assemblies 140 are positioned to perform one or more processing operations to the continuous flexible substrate 108 or web of material. In one example, as depicted in FIG. 1A, the one or more thermal evaporation assemblies 140 are radially disposed about the coating drum 110. In addition, arrangements other than radial are contemplated. In one implementation which can be combined with other implementations, the one or more thermal evaporation assemblies 140 include a lithium (Li) source. Further, the one or more thermal evaporation assemblies 140 can also include a source of an alloy of two or more metals. The material to be deposited can be evaporated, for example, by thermal evaporation techniques.

In operation, the one or more thermal evaporation assemblies 140 emit a plume of evaporated material 122, which is drawn to the continuous flexible substrate 108 where a film of deposited material is formed on the continuous flexible substrate 108.

In addition, although four thermal evaporation assemblies 140a-140d are shown in FIG. 1A, it should be understood that any number of evaporation assemblies can be used. In addition, the processing chamber 100 can further include one or more additional deposition sources. For example, the one or more deposition sources as described herein include an electron beam source and additional sources, which can be selected from the group of CVD sources, PECVD sources, and various PVD sources. Exemplary PVD sources include sputtering sources, electron beam evaporation sources, and thermal evaporation sources. In addition, these additional deposition sources can be positioned radially relative to the deposition surface 111 of the coating drum 110.

In one implementation of the present disclosure which can be combined with other implementations, the processing chamber 100 is configured to process both sides of the continuous flexible substrate 108. For example, additional evaporation assemblies similar to the one or more thermal evaporation assemblies 140 can be positioned to process the opposing side of the continuous flexible substrate 108. Although the processing chamber 100 is configured to process the continuous flexible substrate 108, which is horizontally oriented, the processing chamber 100 can be configured to process substrates positioned in different orientations, for example, the continuous flexible substrate 108 can be vertically oriented. In one implementation of the present disclosure which can be combined with other implementations, the continuous flexible substrate 108 is a flexible conductive substrate. In one implementation of the present disclosure which can be combined with other implementations, the continuous flexible substrate 108 includes a conductive substrate with one or more layers formed thereon. In one implementation of the present disclosure which can be combined with other implementations, the conductive substrate is a copper substrate.

The processing chamber 100 further includes a gas panel 130. The gas panel 130 uses one or more conduits (not shown) to deliver processing gases to the processing chamber 100. The gas panel 130 can include mass flow controllers and shut-off valves, to control gas pressure and flow rate for each individual gas supplied to the processing chamber 100. Examples of gases that can be delivered by the gas panel 130 include, but are not limited to, inert gases for pressure control (e.g., argon), etching chemistries including but not limited to diketones used for in-situ cleaning of the processing chamber 100, and deposition chemistries including but not limited to 1,1,1,2-Tetrafluoroethane or other hydrofluorocarbons and trimethylaluminum, titanium tetrachloride, or other metal organic precursors used for in-situ tens of nanometer thick reactive lithium mixed conductor surface modification.

The processing chamber 100 further includes a system controller 170 operable to control various aspects of the processing chamber 100. The system controller 170 facilitates the control and automation of the processing chamber 100 and can include a central processing unit (CPU), memory, and support circuits (or I/O). Software instructions and data can be coded and stored within the memory for instructing the CPU. The system controller 170 can communicate with one or more of the components of processing chamber 100 via, for example, a system bus. A program (or computer instructions) readable by the system controller 170 determines which tasks are performable on a substrate. In some aspects, the program is software readable by the system controller 170, which can include code for monitoring chamber conditions, including independent temperature control of the one or more evaporation assemblies 140. Although only a single system controller, the system controller 170 is shown, it should be appreciated that multiple system controllers can be used with the aspects described herein.

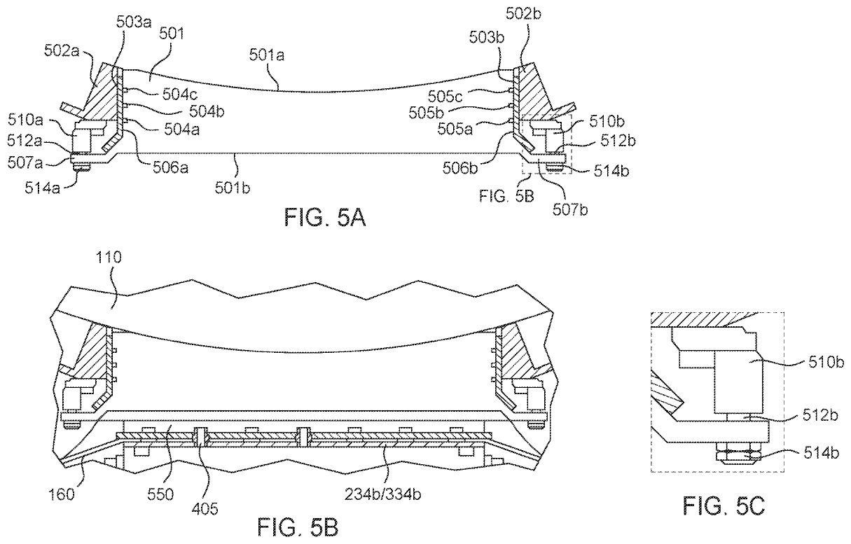

FIG. 1B illustrates a schematic front view of a portion of a processing chamber 150 having an evaporation assembly according to one or more embodiments of the present disclosure. Each of the evaporation assemblies 140a-140d is positioned inside a respective frame 160a-160d (collectively, 160) of the processing chamber 150. The frame 160 supports the evaporation assembly 140. Each evaporation assembly 140 is coupled to the coating drum 110 of the processing chamber 150 via a respective hot shield assembly 152. Embodiments of the hot shield assembly 152 are described below with respect to FIG. 5A-5C. A porous material (not shown) can be disposed between the coating drum 110 and the hot shield assembly 152. The porous material can be porous stainless steel, though other materials are contemplated.

The evaporation assembly 140 includes an evaporator body 158. The evaporator body 158 can be attached to crucible 156. The crucible 156 is designed to hold a material to be evaporated, for example, a metal or metal alloy. The evaporation assembly 140 further includes an alkali metal delivery line 162. An opening (not shown in FIG. 1B) allows positioning of the alkali metal delivery line 162 in a portion of the crucible 156. The alkali metal delivery line 162 extends a certain portion into the crucible 156. The evaporation assembly 140 further includes a plurality of heaters 164. In one implementation which can be combined with other implementations, the heaters 164 are tubular heaters, for example, heating rods.

### Evaporation Assembly for the First Position (A) and the Second Position (B)

FIG. 2A shows a first perspective view of evaporation assembly 200, for example, a thermal evaporator, according to at least one embodiment of the present disclosure. FIG. 2B shows a cross-sectional side view of the evaporation assembly 200 according to at least one embodiment of the present disclosure. FIG. 2C shows a second cross-sectional perspective view of the evaporation assembly 200 with a side removed according to at least one embodiment of the present disclosure. FIG. 2D shows a second side view of the evaporation assembly 200, with a side removed, according to at least one embodiment of the present disclosure. Certain elements are removed for clarity in FIG. 2D relative to FIGS. 2A-2C. In addition, the orientation of elements in FIG. 2D may be different from FIGS. 2A-2C to show the delivery line 262 more clearly.

The evaporation assembly 200 can be used in place of the first evaporation assembly 140a located at the first position (A), in place of the second evaporation assembly 140b located at the second position (B), or combinations thereof.

The evaporation assembly 200 includes a crucible 256 attached to an evaporator body 258. The crucible 256 is designed to hold a material to be evaporated, for example, a metal or metal alloy. The crucible 256 includes a crucible body 214 having a length “L1” dimension and a width “W1” dimension. Although the crucible body 214 is shown as a rectangular body, other suitable shapes for the crucible body 214 are also contemplated. The crucible body 214 includes a top surface 212b having an opening 216 through which the evaporated material can escape. The crucible body 214 further includes a bottom surface 212a opposite the top surface 212b. The crucible body 214 further includes a first pair of opposing sidewalls 220a, 220b (collectively 220) extending upward from and perpendicular to the bottom surface 212a. The first pair of opposing sidewalls 220a, 220b define the length dimension “L1” of the crucible body 214. The crucible body 214 further includes a second pair of opposing sidewalls 222a, 222b (collectively 222) extending upward from and perpendicular to the bottom surface 212a. The second pair of opposing sidewalls 222 define the width dimension “W1” of the crucible body 214. L1 and W1 can also define certain dimensions of the evaporation assembly 200.

The opening 216 of the crucible body 214 can also have a length dimension and width, such as L1 and W1, that define an evaporation surface area. For example, the top surface 212b of the crucible body 214 can be the same as the opening 216 of the crucible body 214.

The bottom surface 212a, the first pair of opposing sidewalls 220, and the second pair of opposing sidewalls 222 define an interior region 226a (shown in FIG. 2C). At least a portion of interior region 226a is operable for holding a material to be evaporated/deposited in a molten and/or liquid form. That is, at least a portion of interior region 226a includes the crucible body 214. The material to be evaporated/deposited can be supplied via delivery line 262 (shown in FIG. 2C) to the interior region 226a of the crucible 256 from an external source 261 (shown in FIG. 2D). The delivery line 262 is discussed further below.

The evaporator body 258 is attached to the crucible 256. Any suitable attachment techniques can be used to attach the crucible 256 to the evaporator body 258. For example, the crucible 256 can be welded to the evaporator body 258. The crucible 256 can be bolted to the evaporator body 258. The crucible 256 can be removably attached to the evaporator body 258. In another implementation, which can be combined with other implementations, the evaporator body 258 and the crucible 256 are machined from a single piece of material. In another implementation, which can be combined with other implementations, the crucible 256 can be integrated within the evaporator body 258.

The crucible 256 and/or the evaporator body 258 can be formed of any suitable material including those materials having high-thermal conductivity. Examples of suitable materials include, but are not limited to, stainless steel, graphite, boron nitride, pyrolytic boron nitride, molybdenum, tungsten, titanium, tantalum, nickel, alloys thereof, or combinations thereof. In at least one embodiment, the crucible 256 and/or the evaporator body 258 is composed of pyrolytic boron nitride. Pyrolytic boron nitride is generally inert, can withstand high temperatures, is generally clean and does not contribute undesirable impurities to the vacuum environment, is generally transparent to certain wavelengths of infrared radiation, and can be fabricated into complex shapes, for example.

The evaporator body 258 is also fluidly coupled with the crucible 256 such that evaporated material from the crucible 256 can travel into the evaporator body 258. Although the evaporator body 258 is shown as a polygonal body, other suitable shapes for the evaporator body 258 are also contemplated.

The evaporator body 258 includes a bottom surface 234a having an opening 236 through which the evaporated material can enter the evaporator body 258 from the opening 216 of the crucible 256. The opening 216 in the top surface 212b of the crucible 256 is aligned with the opening 236 in the bottom surface 234a of the evaporator body 258. In one implementation which can be combined with other implementations, the opening 216 of the crucible 256 and the opening 236 of the evaporator body 258 are the same size. In one implementation which can be combined with other implementations, the opening 216 of the crucible 256 and the opening 236 of the evaporator body 258 are different sizes.

The evaporator body 258 further includes a top surface 234b opposite the bottom surface 234a. In some embodiments, the top surface 234b can be an opening upon which a nozzle assembly is placed (directly or indirectly). In some embodiments, the top surface 234b is a nozzle assembly that includes a plurality of linear arrays of nozzles 235a-235g (collectively 235). Each nozzle 235 has an opening defined by a diameter and a total area of the nozzle openings defines a nozzle opening surface area and the evaporation surface area is greater than the nozzle opening surface area.

The evaporator body 258 further includes a first pair of opposing sidewalls 240a, 240b (collectively 240) extending upward from and perpendicular to the bottom surface 234a. The sidewalls 240 extend downward from the top surface 234b and can be perpendicular to top surface 234b. The first pair of opposing sidewalls 240 of the evaporator body 258 define a length dimension (L2) of the top surface 234b. L2 can also define a length dimension of the evaporator body 258.

The evaporator body 258 further includes a second pair of sidewalls 242a, 242b (collectively 242) extending upward from the bottom surface 234a. Sidewall 242b can be perpendicular to bottom surface 234a.

The evaporator body further includes a third pair of sidewalls 244a, 244b (collectively 244) extending upward from sidewalls 242. The sidewalls 244 extend downward from the top surface 234b and can be perpendicular to the top surface 234b. The third pair of opposing sidewalls 244 of the evaporator body 258 define a width dimension (W2) of the top surface 234b. W2 can also define a width dimension of the evaporator body 258.

The bottom surface 234a, the top surface 234b, the first pair of opposing sidewalls 240, the second pair of sidewalls 242, and the third pair of sidewalls 244 define an interior region 226b for holding the evaporated material.

In some embodiments, sidewall 242b of the evaporator body 258 and sidewall 220b of the crucible 256 can be made to share the same sidewall, for example, when the evaporator body 258 and the crucible 256 are machined from a single piece of material. In at least one embodiment, sidewall 240a of the evaporator body 258 and sidewall 222a of the crucible 256 can be made to share the same sidewall, and sidewall 240b of the evaporator body 258 and sidewall 222b of the crucible 256 can be made to share the same sidewall. This can occur when the evaporator body 258 and the crucible 256 are machined from a single piece of material.

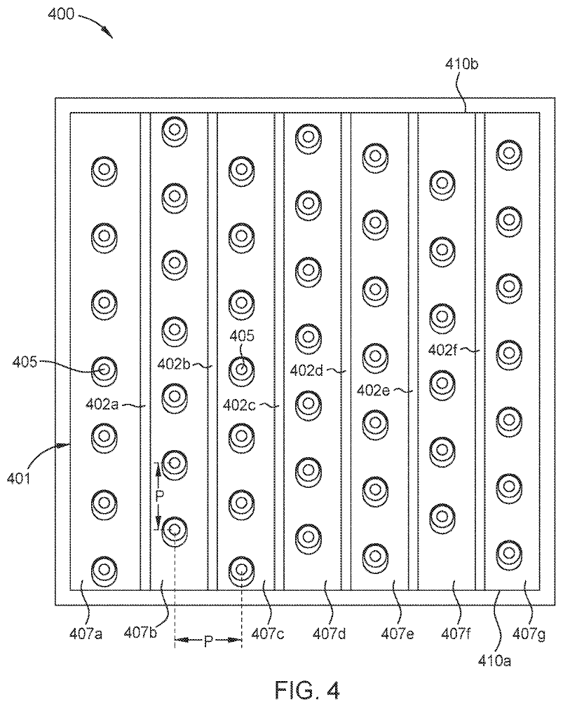

In at least one embodiment which can be combined with other embodiments, the top surface 234b of evaporator body 258 is a planar surface. In some embodiments, and as further described below with respect to FIG. 4, the top surface 234b can include a plurality of longitudinal grooves or a “zig-zag” pattern defining the plurality of longitudinal grooves.

The top surface 234b of the evaporator body 258 can have an angle of inclination on the coating drum 110 that is from about 20 degrees to about 25 degrees, such as from about 21 degrees to about 24 degrees, such as from about 22 degrees to about 23 degrees, such as about 22.5 degrees, though other angles of inclination are contemplated. Any of the foregoing numbers can be used singly to describe an open-ended range or in combination to describe a close-ended range. This angle of inclination is with respect to the bottom plate 180 of the processing chamber 100, 150 (the horizontal plane of the page indicated by dashed line 145).

The evaporation assembly 200 further includes a first heater region 260a and a second heater region 260b. At least a portion of the evaporator body 258 is positioned within the first heater region 260a. The crucible 256 (and/or crucible body 214) is positioned within the second heater region 260b.

The first heater region 260a is positioned between sidewalls 244a, 244b and extends the length dimension (L2) of the evaporator body 258. The first heater region 260a includes a plurality of heaters (for example, heaters 270a, 270b, 270c). The heaters 270a-270c of the first heater region can be positioned/utilized to maintain the evaporated material in a vapor phase and/or cause the evaporated material to be in the vapor phase. The heaters 270a, 270b, and 270c of the first heater region 260a can extend across the length dimension (L2) of the evaporator body 258. The first heater region 260a can further include a first member 272 (for example, a plate), a second member 274 (for example, a plate), or both. The first member 272 can be positioned between heater 270c and sidewall 244b and can extend the length of the sidewall 244b. The first member 272 can be made of a conductive material to prevent (or at least mitigate) radiative heat loss between heater 270c and sidewall 244b. The second member 274 can be positioned between the heater 270a and the sidewall 244a and can extend the length of the sidewall 244a. The second member 274 can be made of a conductive material to prevent (or at least mitigate) radiative heat loss between heater 270a and sidewall 244a. Although the first member 272 and the second member 274 are not shown in FIGS. 2A and 2D, it should be understood that such members are part of evaporation assembly 200.

The second heater region 260b is positioned between the first pair of opposing sidewalls 220, the second pair of opposing sidewalls 222, the top surface 212b, and the bottom surface 212a. The second heater region 260b extends the length dimension (L1) of the crucible 256. The second heater region 260b includes a plurality of heaters (for example, heaters 270d, 270e). The heaters 270d, 270e of the second heater region 260b can be positioned/utilized to heat the material to be evaporated. The heaters 270d, 270e of the second heater region 260b can extend the length dimension (L1) of the crucible 256.

In at least one implementation, which can be combined with other implementations, the heaters 270a-270e can be tubular heaters, for example, heating rods.

In contrast to conventional evaporators that include external crucible heaters, evaporation assembly 200 described herein can be free of such external crucible heaters. Here, removal of the external crucible heater can reduce the heat load spacing between the heaters 270a-270e (for example, heating rods). In addition, conventional evaporation assemblies can suffer from radiative heat loss between the interior region of the evaporator and the sidewalls. In contrast, embodiments described herein include members 272, 274 to mitigate (or prevent) radiative heat loss. Further, the positioning of the heaters 270a-270e of embodiments described herein is different from conventional evaporation assemblies.

Aside from external heaters, conventional evaporation assemblies include only a single region of heaters with the single region of heaters positioned above the crucible and in the evaporator body. That is, all of the heaters are located at a position above the crucible. In contrast, and as described above, embodiments of the present disclosure can include two or more heater regions. For example, the second heater region 260b can be used to heat the material to be evaporated, and the first heater region can be utilized to keep the evaporated material in a vapor phase. The positioning of the heater regions 260a, 260b, the heaters 270a-270e, and the members 272, 274 can enable significantly less radiative heat loss than that observed with conventional evaporation assemblies. Moreover, the positioning of the heater regions 260a, 260b, the heaters 270a-270e, and the members 272, 274 can mitigate (or prevent) condensation of metal/metal alloy on the evaporator body 258.

In some embodiments, dimensions W1×L1 of the opening 216 of the crucible body 214 can be from about 150 mm×370 mm to about 200 mm×450 mm, such as from about 160 mm×380 mm to about 190 mm×440 mm, such as from about 170 mm×400 mm to about 180 mm×420 mm, or about 170 mm×420 mm, though other dimensions are contemplated. Any of the foregoing numbers can be used singly to describe an open-ended range or in combination to describe a close-ended range.

In some embodiments, the opening 216 of the crucible body 214 can have an area that is from about 50,000 mm² to about 100,000 mm², such as from about 60,000 mm² to about 90,000 mm², such as from about 70,000 mm² to about 80,000 mm², such as from about 70,000 mm² to about 75,000 mm², though other areas are contemplated. Any of the foregoing numbers can be used singly to describe an open-ended range or in combination to describe a close-ended range.

The dimensions W1×L1 of the opening 216 of the crucible body 214 and the area of the opening 216 of the crucible body 214 are significantly larger than conventional crucibles. For example, certain conventional crucibles, such as cylindrical crucibles, have a diameter of about 45 mm and a crucible opening area of about 135 mm². Other conventional crucibles (for example, those with compartments) have a crucible opening of about 145 mm×320 mm and a crucible opening area of about 47,000 mm².

Crucibles described herein (for example, crucible 256) have a significantly larger volume capacity than conventional crucibles. For example, while conventional crucibles have a volume capacity of 2.8 liters (L) or less, crucibles described herein (for example, crucible 256) can have a volume capacity that is from about 4.5 L to about 5.5 L, such as from about 4.8 to about 5.2 L, though other values are contemplated. Any of the foregoing numbers can be used singly to describe an open-ended range or in combination to describe a close-ended range. The increased volume capacity of crucible 256 can enable, for example, longer runs.

In some embodiments, the top surface 234b of the evaporator body 258 can have an area that is from about 90,000 mm² to about 120,000 mm², such as from about 95,000 mm² to about 115,000 mm², such as from about 100,000 mm² to about 110,000 mm², such as from about 100,000 mm² to about 105,000 mm², though other areas are contemplated. Any of the foregoing numbers can be used singly to describe an open-ended range or in combination to describe a close-ended range. The area of the top surface 234b can be referred to as the evaporator opening area. Conventional evaporation assemblies, in contrast, have an evaporator top surface with an area of less than 90,000 mm².

As described further below, the evaporation assemblies described herein can include a nozzle assembly (for example, nozzle assembly 400 shown in FIG. 4) having more than 50 nozzles, the typical number of nozzles for conventional evaporation assemblies. For example, nozzle assemblies described herein can include about 50 or more nozzles, such as about 60 nozzles or more, such as about 70 nozzles or more, or other suitable numbers of nozzles. Any of the foregoing numbers can be used singly to describe an open-ended range or in combination to describe a close-ended range. When evaporation assemblies described herein are operated at the same temperature as conventional evaporation assemblies, the increased number of nozzles can enable higher deposition rates than conventional evaporation assemblies. When evaporation assemblies described herein are operated at a lower temperature than conventional evaporation assemblies, the increased number of nozzles can enable similar deposition rates.

In some embodiments, a total nozzle opening area of the evaporation assembly for the first position (A) and/or the second position (B) (for example, evaporation assembly 200) can be greater than about 1,000 mm², such as from about 1,000 mm² to about 1,500 mm², such as from about 1,100 mm² to about 1,450 mm², such as from about 1,300 mm² to about mm², such as from about 1,350 mm² to about 1,400 mm², though other values are contemplated. Any of the foregoing numbers can be used singly to describe an open-ended range or in combination to describe a close-ended range. The total nozzle opening area is based on the total number of nozzles multiplied by πr², where r is the radius of the nozzle opening (about 2.5 mm). Conventional evaporator assemblies have a total nozzle opening area that is less than 1,000 mm².

In some embodiments, and for evaporation assembly 200, an area ratio of (a) the evaporator opening area (the area of the top surface 234b) to (b) the total nozzle opening area is from about 50:1 to about 85:1, such as from about 55:1 to about 80:1, such as from about 60:1 to about 75:1, such as from about 65:1 to about 75:1, such as from about 70:1 to about 75:1. Any of the foregoing numbers can be used singly to describe an open-ended range or in combination to describe a close-ended range. Calculating the evaporator opening area (the area of the top surface 234b) and the total nozzle opening area are described above. The ratio is then calculated from dividing the evaporator opening area (the area of the top surface 234b) by the total nozzle opening area. In contrast, conventional evaporator assemblies have an area ratio of the evaporator opening area to the total nozzle opening area have a total nozzle opening area that is greater than 85:1.

Evaporation assemblies described herein (for example, evaporation assembly 200) includes a crucible having a larger body relative to conventional crucibles. The larger body can enable larger volumes (in some examples, about 4.5 L or more, such as about 5 L or more) of alkali metal to be utilized and therefore longer run-to-run lengths can be achieved. As opposed to conventional apparatus which utilize cylindrical crucibles, evaporation assemblies described herein can have a rectangular shape. The rectangular shape can enable, for example, a uniform surface area from which the alkali metal is evaporated.

The rectangular shape of the evaporation assembly can also minimize the depletion effect of alkali metal observed with conventional crucibles. This depletion effect can be observed in state-of-the-art evaporators where a crucible has various compartments. When one or more of the compartments become depleted of the alkali metal during a run (when the vacuum is turned on), the liquid-to-vapor interface shrinks. In contrast, embodiments of evaporation assemblies described herein enable the liquid-to-vapor interface to stay approximately constant throughout a run, therefore preventing (or at least minimizing) the depletion effect observed with conventional evaporators. Moreover, crucibles described herein are free of compartments. By not including compartments, the crucibles described herein can avoid over-filling of alkali metal into other portions of the evaporator body.

In further contrast to conventional evaporation assemblies which utilize external heaters to heat the crucibles by radiative heating, evaporation assemblies described herein (for example, evaporation assembly 200) are free of an external heater. Instead, evaporation assemblies described herein (for example, evaporation assembly 200) include a heating region (for example, heater region 260b) that is not external to the crucible. The heater region can enable conductive heating rather than radiative heating observed in conventional technologies. Many other differences from conventional evaporator assemblies are described herein, including the configuration and placement of delivery line 262 (described below).

The delivery line 262 (for example, an alkali metal delivery line) is illustrated in FIG. 2D. The delivery line 262 can have a clam shell profile. The delivery line 262 can be a heated line, such that the delivery line 262 can help maintain the material to be evaporated in a liquid (or molten) state.

The delivery line 262 couples the external source 261 to the interior region 226a of the crucible 256. The external source 261 holds the material to be evaporated/deposited (for example, alkali metal). The material to be evaporated/deposited can be supplied via delivery line 262 to the interior region 226a of the crucible 256 from the external source 261.

The delivery line 262 includes various sections—a first section 263 (also called an exterior portion), a second section 264 (also called a first interior portion), and a third section 265 (also called a second interior portion). The sections 263, 264, 265 can be attached to one another by any suitable technique. Any suitable attachment techniques can be used to attach the crucible 256 to the evaporator body 258. For example, the sections 263, 264, 265 can be welded to one another. The sections 263, 264, 265 can be bolted to one another. The sections 263, 264, 265 can be removably attached to one another. In another implementation, which can be combined with other implementations, the sections 263, 264, 265 can be machined from a single piece of material.

The exterior portion 263 of the delivery line 262 is positioned exterior to the evaporation assembly 200. The exterior portion 263 of the delivery line 262 includes a first end 263a and a second end 263b. The first end 263a can be coupled to an interior of external source 261. As such, the first end 263a can serve as an inlet through which the material to be evaporated/deposited enters the delivery line 262. In some embodiments, the exterior portion 263 of the delivery line 262 has a length (from first end 263a to second end 263b) that is from about 500 mm to about 600 mm, such as from about 525 mm to about 575 mm, such as from about 540 mm to about 550 mm, though other lengths are contemplated. Any of the foregoing numbers can be used singly to describe an open-ended range or in combination to describe a close-ended range.

The first interior portion 264 and second interior portion 265 of the delivery line 262 are positioned in the interior of the evaporation assembly 200. One or both of the first interior portion 264 and second interior portion 265 of the delivery line 262 can traverse the evaporator body 258 and the crucible 256. In the embodiment shown in FIG. 2D, the first interior portion 264 of the delivery line 262 traverses the evaporator body 258 and the crucible 256.

The first interior portion 264 of the delivery line 262 includes a first end 264a and a second end 264b. The second interior portion 265 of the delivery line 262 includes a first end 265a and a second end 265b. The first end 264a of the first interior portion 264 is attached to the second end 263b of the exterior portion 263. The second end 264b of the first interior portion 264 is attached to the first end 265a of the second interior portion 265. The second end 265b of the second interior portion (which also represents an end of the delivery line 262) can be a closed end. The first interior portion 264 of the delivery line 262 extends from an opening 266 in the sidewall 242a of the evaporator body 258 to the interior region 226a of the crucible 256 and below the top surface 212b of the crucible body 214.

In some embodiments, the second interior portion 265 of the delivery line 262 has a length (from first end 265a to second end 265b) that is from about 200 mm to about 350 to about 600 mm, such as from about 225 mm to about 325 mm, such as from about 250 mm to about 300 mm, though other lengths are contemplated. Any of the foregoing numbers can be used singly to describe an open-ended range or in combination to describe a close-ended range.

The delivery line further includes a plurality of openings 266a-266c (collectively, 266) through which alkali metal can exit the delivery line 262 into the crucible 256. The openings are positioned along the second interior portion 265 of the delivery line 262. The openings 266a-266c can be of any suitable size, such as a diameter from about 1 mm to about 5 mm, such as from about 2 mm to about 4 mm, such as about 3 mm. Any of the foregoing numbers can be used singly to describe an open-ended range or in combination to describe a close-ended range. In some embodiments, a length from 265a to one of the openings 266 can be from about 250 mm to about 300 mm, such as from about 260 mm to about 275 mm, though other lengths are contemplated. Any of the foregoing numbers can be used singly to describe an open-ended range or in combination to describe a close-ended range.

During operation, the top surface 212b can represent the maximum fill line of the crucible. Further, and during operation, the second interior portion 265 of the delivery line 262 is immersed in the material to be evaporated/deposited (e.g., the liquid pool of alkali metal). Such configuration enables for improved temperature equalization during alkali metal delivery at processing temperatures.

That is, the delivery line 262 enables better temperature uniformity of the alkali metal to be evaporated/deposited. For example, the second interior portion 265 of the delivery line 262 can have only a 1 degree difference between the first end 265a and the second end 265b.

Delivery lines described herein have advantages over the state-of-the-art. Conventional evaporator systems include delivery lines having a series of openings allowing delivery of alkali metal into compartments of the crucible. During use, conventional delivery lines are not immersed in the liquid pool of alkali metal. For example, and referring to FIG. 2, conventional delivery lines include an outlet through which alkali metal is delivered to the crucible. This outlet of conventional crucibles is located along section 264 near to first end 264a, such that the outlet is positioned above the crucible. Because the outlet is positioned above the crucible, the alkali metal splashes as the alkali metal is delivered to the crucible.

In contrast, delivery lines described herein (for example, delivery line 262) can be longer, positioned further into the evaporation assembly, and are immersed in the liquid pool of alkali metal during operation, thereby avoiding splashing. For example, the horizontal portion of the delivery line which is positioned in the crucible can be about 305 mm. Alkali metal delivery lines described herein can include any suitable number of openings through which alkali metal exits the alkali metal delivery line and into the crucible. The alkali metal delivery line can be positioned in the evaporation assembly such that the line is immersed in the pool of alkali metal (in the crucible) during operation. Such configuration enables for improved temperature equalization during alkali metal delivery at processing temperatures. That is, the alkali metal delivery line enables better temperature uniformity of the alkali metal inside the evaporator. For example, the horizontal portion of the delivery line 262 inside the evaporator (for example, the third section 265) can have only a 1 degree difference between the first end 265a and the second end 265b (closed end). In addition, the delivery line 262 can enable replenishment of alkali metal during operation without splashing as the delivery line 262 is immersed during operation.

### Evaporation Assembly for the Third Position (C) and the Fourth Position (D)

FIG. 3A shows a perspective view of evaporation assembly 300, for example, a thermal evaporator, according to at least one embodiment of the present disclosure. FIG. 3B shows a side view of the evaporation assembly 300 according to at least one embodiment of the present disclosure. The evaporation assembly 300 can be used in place of the third evaporation assembly 140c located at the first position (C), in place of the fourth evaporation assembly 140d located at the second position (D), or combinations thereof.

The evaporation assembly 300 includes a crucible 356 attached to an evaporator body 358. The crucible 356 is designed to hold a material to be evaporated, for example, a metal or metal alloy. The crucible 356 includes a crucible body 314 having a length “L3” dimension and a width “W3” dimension. Although the crucible body 314 is shown as a rectangular body, other suitable shapes for the crucible body 314 are also contemplated. The crucible body 314 includes a top surface 312b having an opening 316 through which the evaporated material can escape. The crucible body 314 further includes a bottom surface 312a opposite the top surface 312b. The crucible body 314 further includes a first pair of opposing sidewalls 320a, 320b (collectively 320) extending upward from and perpendicular to the bottom surface 312a. The first pair of opposing sidewalls 320a, 320b define the length dimension “L3” of the crucible body 314. The crucible body 314 further includes a second pair of opposing sidewalls 322a, 322b (collectively 322) extending upward from and perpendicular to the bottom surface 312a. The second pair of opposing sidewalls 322 define the width dimension “W3” of the crucible body 214. L3 and W3 can also define certain dimensions of the evaporation assembly 300.

The opening 316 of the crucible body 314 can also have a length dimension and width, such as L3 and W3, that define an evaporation surface area. For example, the top surface 312b of the crucible body 314 can be the same as the opening 316 of the crucible body 314.

The bottom surface 312a, the first pair of opposing sidewalls 320, and the second pair of opposing sidewalls 322 define an interior region (not shown; similar to interior region 226a) of the crucible 356. At least a portion of interior region of the crucible is operable for holding a material to be evaporated/deposited in a molten and/or liquid form. That is, at least a portion of interior region includes the crucible body 314. The material to be evaporated/deposited can be supplied via delivery line 362 to the interior region of the crucible 356 from an external source (not shown; similar to external source 261). The delivery line 362 can be the same as or similar to delivery line 262 described above.

The evaporator body 358 is attached to the crucible 356. Any suitable attachment techniques can be used to attach the crucible 356 to the evaporator body 358. For example, the crucible 356 can be welded to the evaporator body 358. The crucible 356 can be bolted to the evaporator body 358. The crucible 356 can be removably attached to the evaporator body 358. In another implementation, which can be combined with other implementations, the evaporator body 358 and the crucible 356 are machined from a single piece of material. In another implementation, which can be combined with other implementations, the crucible 356 can be integrated within the evaporator body 358.

The crucible 356 and/or the evaporator body 358 can be formed of any suitable material including those materials having high-thermal conductivity. Examples of suitable materials include, but are not limited to, stainless steel, graphite, boron nitride, pyrolytic boron nitride, molybdenum, tungsten, titanium, tantalum, nickel, alloys thereof, or combinations thereof. In at least one embodiment, the crucible 356 and/or the evaporator body 358 is composed of pyrolytic boron nitride. Pyrolytic boron nitride is generally inert, can withstand high temperatures, is generally clean and does not contribute undesirable impurities to the vacuum environment, is generally transparent to certain wavelengths of infrared radiation, and can be fabricated into complex shapes, for example.

The evaporator body 358 is also fluidly coupled with the crucible 356 such that evaporated material from the crucible 356 can travel into the evaporator body 358. Although the evaporator body 358 is shown as a polygonal body, other suitable shapes for the evaporator body 358 are also contemplated.

The evaporator body 358 includes a bottom surface 334a having an opening 336 through which the evaporated material can enter the evaporator body 358 from the opening 316 of the crucible 356. The opening 316 in the top surface 312b of the crucible 356 is aligned with the opening 336 in the bottom surface 334a of the evaporator body 358. In one implementation which can be combined with other implementations, the opening 316 of the crucible 356 and the opening 336 of the evaporator body 358 are the same size. In one implementation which can be combined with other implementations, the opening 316 of the crucible 356 and the opening 336 of the evaporator body 358 are different sizes.

The evaporator body 358 further includes a top surface 334b opposite the bottom surface 334a. In some embodiments, the top surface 334b can be an opening upon which a nozzle assembly is placed (directly or indirectly). In some embodiments, the top surface 334b is a nozzle assembly that includes a plurality of linear arrays of nozzles (not shown; similar to the plurality of linear arrays of nozzles 235a-235g). Each nozzle has an opening defined by a diameter. A total area of the nozzle openings defines a nozzle opening surface area and the evaporation surface area is greater than the nozzle opening surface area.

The evaporator body 358 further includes a first pair of opposing sidewalls 340a, 340b (collectively 340) extending upward from and perpendicular to the bottom surface 334a. The sidewalls 340 extend outward from the top surface 334b and can be perpendicular to top surface 334b. The sidewalls 340 also extend outward from sidewall 343. The first pair of opposing sidewalls 340 of the evaporator body 358 define a length dimension (L4) of the top surface 334b. L4 can also define a length dimension of the evaporator body 358.

The evaporator body 358 further includes a second pair of opposing sidewalls 344a, 344b (collectively 344) extending outward from the top surface 334b and can be perpendicular to the top surface 334b. The second pair of opposing sidewalls 344 of the evaporator body 358 define a width dimension (W4) of the top surface 334b. W4 can also define a width dimension of the evaporator body 358.

The evaporator body 358 further includes a sidewall 343 that extends downward from and perpendicular to bottom surface 334a. The sidewall 343 of the evaporator body 358 corresponds to sidewall 320a of the crucible. The evaporator body 358 further includes a sidewall 342a extending outward from and perpendicular to sidewall 343. Sidewall 342a also extends outward from sidewall 344a. Sidewall 342a is parallel to bottom surface 334a. The evaporator body further includes sidewall 342b that extends outward from bottom surface 334a, sidewall 344b, and sidewall 340b. Sidewall 342b and bottom surface 334a meet at an angle that is less than perpendicular.

The bottom surface 334a, the top surface 334b, the first pair of opposing sidewalls 340, the second pair of sidewalls 344, sidewalls 342a, 342b, and 343 define an interior region (not shown; similar to interior region 226b) for holding the evaporated material.

In some embodiments, sidewall 342b of the evaporator body 358 and sidewall 320b of the crucible 356 can be made to share the same sidewall, for example, when the evaporator body 358 and the crucible 356 are machined from a single piece of material. In at least one embodiment, sidewall 340a of the evaporator body 358 and sidewall 322a of the crucible 356 can be made to share the same sidewall, and sidewall 340b of the evaporator body 358 and sidewall 322b of the crucible 356 can be made to share the same sidewall. This can occur when the evaporator body 358 and the crucible 356 are machined from a single piece of material.

In at least one embodiment which can be combined with other embodiments, the top surface 334b of evaporator body 358 is a planar surface. In some embodiments, and as further described below with respect to FIG. 4, the top surface 334b can include a plurality of longitudinal grooves or a “zig-zag” pattern defining the plurality of longitudinal grooves.

The top surface 334b of the evaporator body 358 can have an angle of inclination on the coating drum 110 that is from about 65 degrees to about 70 degrees, such as from about 66 degrees to about 69 degrees, such as from about 67 degrees to about 68 degrees, such as about 67.5 degrees, though other angles of inclination are contemplated. Any of the foregoing numbers can be used singly to describe an open-ended range or in combination to describe a close-ended range. The angle of inclination is with respect to the bottom plate 180 of the processing chamber 100, 150 (the horizontal plane of the page indicated by the dashed line 145).

The evaporation assembly 300 further includes a first heater region 360a, a second heater region 360b, and a third heater region 360c. At least a first portion of the evaporator body 358 is located in the first heater region 360a. At least a second portion of the evaporator body 358 is positioned within the second heater region 360b. The crucible 356 (and the crucible body 314) is located inside the third heater region 360c, and outside of the first heater region 360a and the second heater region 360b.

The first heater region 360a is positioned between sidewalls 344a, 344b and extends the length dimension (L4) of the evaporator body. The first heater region 360a includes a plurality of heaters (for example, heaters 370a, 370b, 370c). The heaters 370a-370c of the first heater region 360a can be utilized to maintain the evaporated material in a vapor phase and/or cause the evaporated material to be in the vapor phase. The heaters 370a, 370b, and 370c of the first heater region 360a can extend across the length dimension (L4) of the evaporator body 358. The first heater region 360a can further include a first member 372 (for example, a plate), a second member 374 (for example, a plate), or both. The first member 372 can be positioned between heater 370c and sidewall 344b and can extend the length of the sidewall 344b. The first member 372 can be made of a conductive material to prevent (or at least mitigate) radiative heat loss between heater 370c and sidewall 344b. The second member 374 can be positioned between the heater 370a and the sidewall 344a and can extend the length of the sidewall 344a. The second member 374 can be made of a conductive material to prevent (or at least mitigate) radiative heat loss between heater 370a and sidewall 344a.

The second heater region 360b is positioned between bottom surface 334a and sidewall 342b of the evaporator body 358 and extends the length dimension (L4) of the evaporator body 358. The second heater region 360b includes a heater 370d, though more than one heater is contemplated. The heater 370d of the second heater region 360b can be utilized to maintain the evaporated material in a vapor phase and/or cause the evaporated material to be in the vapor phase. Although not shown, the second heater region can further include a member (for example, a plate) positioned between heater 370d and sidewall 342b and can extend the length of the sidewall 342b. The member can be similar to first member 372 or second member 374 of the first heater region 360a, and can be utilized to prevent (or at least mitigate) radiative heat loss between heater 370d and sidewall 342b.

The third heater region 360c is positioned between the first pair of opposing sidewalls 320, the second pair of opposing sidewalls 322, the top surface 312b, and the bottom surface 312a. The third heater region 360c extends the length dimension (L3) of the crucible 356. The third heater region 360c includes a heater 370e, though more than one heater is contemplated. The heater 370e of the third heater region 360c can be positioned/utilized to heat the material to be evaporated.

In at least one implementation, which can be combined with other implementations, the heaters 370a-370e can be tubular heaters, for example, heating rods.

In contrast to conventional evaporators that include external crucible heaters, evaporation assembly 300 described herein can be free of such external crucible heaters. Here, removal of the external crucible heater can reduce the heat load spacing between the heaters 370a-370e (for example, heating rods). In addition, conventional evaporation assemblies can suffer from radiative heat loss between the interior region of the evaporator and the sidewalls. In contrast, embodiments described herein include members 372, 374 to mitigate (or prevent) radiative heat loss. Further, the positioning of the heaters 370a-370e of embodiments described herein is different from conventional evaporation assemblies.

Aside from external heaters, conventional evaporation assemblies include only a single region of heaters with the single region of heaters positioned above the crucible and in the evaporator body. All of the heaters in conventional assemblies are located at a position above the crucible and near to nozzle assemblies. In contrast, and as described above, evaporation assembly can include three or more heater regions.

For example, the third heater region 360c can be used to heat the material to be evaporated, while the first heater region 360a and second heater region 360b can be utilized to keep the evaporated material in a vapor phase. The positioning of the heater regions 360a-360c, the heaters 370a-370e, and the members 372, 374 can enable significantly less radiative heat loss than that observed with conventional evaporation assemblies. Moreover, the positioning of the heater regions 360a-360c, the heaters 370a-370e, and the members 372, 374 can mitigate (or prevent) condensation of metal/metal alloy on the evaporator body 358.

The dimensions of the opening 316 of the crucible body 314 for evaporation assembly 300 can be the same as or different than those of the opening 216 of the crucible body 214 for evaporation assembly 200. In at least one embodiment, the dimensions of the opening 316 of the crucible body 314 for evaporation assembly 300 can be smaller than those of the opening 316 of the crucible body 314 for evaporation assembly 300.

The dimensions of the top surface 334b of the evaporator body 358 for evaporation assembly 300 can be the same as or different than those of the top surface 234b of the evaporator body 258 for evaporation assembly 200. In at least one embodiment, the dimensions of the top surface 334b of the evaporator body 358 for evaporation assembly 300 are the same (or about the same) as those of the top surface 234b of the evaporator body 258 for evaporation assembly 200.

In some embodiments, dimensions W3×L3 of the opening 316 of the crucible body 314 can be from about 145 mm×350 mm to about 200 mm×450 mm, such as from about 150 mm×360 mm to about 190 mm×440 mm, such as from about 160 mm×400 mm to about 180 mm×420 mm, or from about 160 mm×400 to about 170 mm×420 mm, though other dimensions are contemplated. Any of the foregoing numbers can be used singly to describe an open-ended range or in combination to describe a close-ended range.

In some embodiments, the opening 316 of the crucible body 314 can have an area that is from about 45,000 mm² to about 100,000 mm², such as from about 50,000 mm² to about 90,000 mm², such as from about 60,000 mm² to about 80,000 mm², such as from about 65,000 mm² to about 70,000 mm², though other areas are contemplated. Any of the foregoing numbers can be used singly to describe an open-ended range or in combination to describe a close-ended range.

The dimensions W3×L3 of the opening 316 of the crucible body 314 and the area of the opening 316 of the crucible body 314 are significantly larger than conventional crucibles. For example, certain cylindrical crucibles have a diameter of about 45 mm and a crucible opening area of about 135 mm². Other conventional crucibles (for example, those with compartments) have a crucible opening of about 145 mm×320 mm and a crucible opening area of about 47,000 mm².

Crucibles described herein (for example, crucible 356) have a significantly larger volume capacity than conventional crucibles. For example, while conventional crucibles have a volume capacity of 2.8 L or less, crucible 356 can have a volume capacity that is from about 4.3 L to about 5.3 L, such as from about 4.5 to about 5 L, though other values are contemplated. Any of the foregoing numbers can be used singly to describe an open-ended range or in combination to describe a close-ended range. The increased volume capacity of crucible 356 can enable, for example, longer runs.

In some embodiments, the top surface 334b of the evaporator body 358 can have an area that is from about 90,000 mm² to about 120,000 mm², such as from about 95,000 mm² to about 115,000 mm², such as from about 100,000 mm² to about 110,000 mm², such as from about 100,000 mm² to about 105,000 mm², though other areas are contemplated. Any of the foregoing numbers can be used singly to describe an open-ended range or in combination to describe a close-ended range. The area of the top surface 334b can be referred to as the evaporator opening area. Conventional evaporation assemblies, in contrast, have an evaporator top surface with an area of less than 90,000 mm².

As described further below, the evaporation assemblies described herein can include a nozzle assembly (for example, nozzle assembly 400 shown in FIG. 4) having more than 50 nozzles, the typical number of nozzles for conventional evaporation assemblies. For example, nozzle assemblies described herein can include about 50 or more nozzles, such as about 60 nozzles or more, such as about 70 nozzles or more, or other suitable numbers of nozzles. Any of the foregoing numbers can be used singly to describe an open-ended range or in combination to describe a close-ended range. When evaporation assemblies described herein are operated at the same temperature as conventional evaporation assemblies, the increased number of nozzles can enable higher deposition rates than conventional evaporation assemblies. When evaporation assemblies described herein are operated at a lower temperature than conventional evaporation assemblies, the increased number of nozzles can enable similar deposition rates.

In some embodiments, a total nozzle opening area of the evaporation assembly for the third position (C) and/or the fourth position (D) (for example, evaporation assembly 300) can be greater than about 1,000 mm², such as from about 1,000 mm² to about 1,500 mm², such as from about 1,100 mm² to about 1,450 mm², such as from about 1,300 mm² to about mm², such as from about 1,350 mm² to about 1,400 mm², though other values are contemplated. Any of the foregoing numbers can be used singly to describe an open-ended range or in combination to describe a close-ended range. The total nozzle opening area is based on the total number of nozzles multiplied by πr², where r is the radius of the nozzle opening (about 2.5 mm). Conventional evaporator assemblies have a total nozzle opening area that is less than 1,000 mm².

In some embodiments, and for evaporation assembly 300, an area ratio of (a) the evaporator opening area (the area of the top surface 334b) to (b) the total nozzle opening area is from about 50:1 to about 85:1, such as from about 55:1 to about 80:1, such as from about 60:1 to about 75:1, such as from about 65:1 to about 75:1, such as from about 70:1 to about 75:1. Any of the foregoing numbers can be used singly to describe an open-ended range or in combination to describe a close-ended range. Calculating the evaporator opening area (the area of the top surface 334b) and the total nozzle opening area are described above. The ratio is then calculated from dividing the evaporator opening area (the area of the top surface 334b) by the total nozzle opening area. In contrast, conventional evaporator assemblies have an area ratio of the evaporator opening area to the total nozzle opening area that is greater than 85:1.

Evaporation assemblies described herein (for example, evaporation assembly 300) includes a crucible having a larger body relative to conventional crucibles. The larger body can enable larger volumes (in some examples, about 4.3 L or more, such as about 4.8 L or more) of alkali metal to be utilized and therefore longer run-to-run lengths can be achieved. Any of the foregoing numbers can be used singly to describe an open-ended range or in combination to describe a close-ended range. As opposed to conventional apparatus which utilize cylindrical crucibles, evaporation assemblies described herein can have a rectangular shape. The rectangular shape can enable, for example, a uniform surface area from which the alkali metal is evaporated.

The rectangular shape of the evaporation assembly can also minimize the depletion effect of alkali metal observed with conventional crucibles. This depletion effect can be observed in state-of-the-art evaporators where a crucible has various compartments. When one or more of the compartments become depleted of the alkali metal during a run (when the vacuum is turned on), the liquid-to-vapor interface shrinks. In contrast, embodiments of evaporation assemblies described herein enable the liquid-to-vapor interface to stay approximately constant throughout a run, therefore preventing (or at least minimizing) the depletion effect observed with conventional evaporators. Moreover, crucibles described herein are free of compartments. By not including compartments, the crucibles described herein can avoid over-filling of alkali metal into other portions of the evaporator body.

In further contrast to conventional evaporation assemblies which utilize external heaters to heat the crucibles by radiative heating, evaporation assemblies described herein (for example, evaporation assembly 300) are free of an external heater. Instead, evaporation assemblies described herein (for example, evaporation assembly 300) include a heating region (for example, third heater region 360c) that is not external to the crucible. The heater region can enable conductive heating rather than radiative heating observed in conventional technologies. Many other differences from conventional evaporator assemblies are described herein, including the configuration and placement of delivery line 262 (described above).

### Nozzle Assembly

FIG. 4 shows a nozzle assembly 400 according to at least one embodiment of the present disclosure. The nozzle assembly 400 can be used with any suitable evaporation assembly (for example, evaporation assembly 200 and/or evaporation assembly 300). For example, nozzle assembly 400 can be used in place of the top surface 234b or the top surface 334b.

In one embodiment which can be combined with other embodiments, the top surface 401 of the nozzle assembly 400 is a planar surface. In another embodiment which can be combined with other embodiments, the top surface 401 includes a plurality of longitudinal grooves 402a-402f (collectively 402) or a “zig-zag” pattern defining the plurality of longitudinal grooves. The longitudinal grooves 402 separate a plurality of longitudinal peaks 407a-407g (collectively 407). Although six longitudinal grooves 402a-402f are shown, the number of longitudinal grooves can be increased or decreased depending upon the desired surface area of an evaporator body (for example, evaporator body 258 or evaporator body 358). Similarly, although seven longitudinal peaks 407a-407g are shown, the number of longitudinal peaks can be increased or decreased depending upon the desired surface area of an evaporator body (for example, evaporator body 258 or evaporator body 358).

When positioned on an evaporator body, the grooved design of the top surface 401 can increase the surface area of the evaporator body 258 (or evaporator body 358), which reduces the amount of radiative heat that the web substrate is exposed to. This increased surface area of the top surface 234b (or top surface 334b) helps achieve higher vapor pressures at lower temperatures.

Each longitudinal peak 407a-407g supports a linear array of nozzles 405 configured to deliver evaporated material toward the surface of the web. As shown in FIG. 4, the nozzle assembly includes seven longitudinal peaks 407a-407g, and each longitudinal peak supports 10 nozzles 405 for a total of 70 nozzles 405. A pitch (“P”) between each nozzle 405 can be from about 30 millimeters (mm) to about 40 mm, such as from about 32 mm to about 38 mm, such as about 35 mm. Any of the foregoing numbers can be used singly to describe an open-ended range or in combination to describe a close-ended range.

Each nozzle 405 includes an opening defined by a diameter. The opening of the nozzles can be any diameter sufficient to deliver the evaporated material at desired vapor pressures. In one implementation which can be combined with other implementations, each nozzle 405 has an opening defined by a diameter that is from about 1 mm to about 10 mm, for example, from 3 mm to about 7 mm, such as from about 4.5 mm to about 5.5 mm, such as about 5 mm. Any of the foregoing numbers can be used singly to describe an open-ended range or in combination to describe a close-ended range.

The height of the nozzle 405 can vary. In one implementation which can be combined with other implementations, the height of the nozzle 405 can be from about 10 mm to about 20 mm, such as from about 10 mm to about 15 mm, from about 15 mm to about 20 mm, or about 15 mm. Any of the foregoing numbers can be used singly to describe an open-ended range or in combination to describe a close-ended range.

As described above, conventional nozzle assemblies include only 50 nozzles (five rows with 10 nozzles in each row), whereas embodiments described herein include more than about 50 nozzles, such as about 60 nozzles or more, such as about 70 nozzles or more (for example 7 longitudinal peaks 407 (or 7 rows) with 10 nozzles 405 in each longitudinal peak 407 (or in each row)). Any of the foregoing numbers can be used singly to describe an open-ended range or in combination to describe a close-ended range. Here, the inventors found that, for example, a reduced pitch between the nozzles can accommodate 2 additional rows of nozzles.

The increased number of nozzles can provide higher deposition rates, or even similar rates at lower temperatures.

Increasing the number of nozzles is not obvious or straightforward. With a given area, for example, the evaporator opening area (the area of the top surface 234b, 334b), one cannot randomly change the number of nozzles to achieve high deposition rates. First, one must have a higher temperature to achieve the same amount of flux in order for the alkali metal to go through the higher number of nozzles. Second, even if one has a higher number of nozzles, the substrate 108 is negatively impacted during processing. Here, increasing the number of nozzles can lead to non-uniformity of the film and increased amounts of condensation heat load that would damage the foil due to the higher pressures and temperatures needed to force the alkali metal out of the nozzles. These and other considerations make the nozzle assemblies described herein not an obvious design choice. As a result of, at least, the evaporator opening area and the nozzle area of embodiments described herein, the nozzle assemblies of the present disclosure can achieve uniform films and little to no condensation during processing of a substrate 108.

### Hot Shield Assembly

FIGS. 5A-5C show a hot shield assembly 500 according to one or more implementations of the present disclosure. Specifically, FIG. 5A shows the hot shield assembly 500, FIG. 5B shows a mounting mechanism 510b for the hot shield 501, and FIG. 5C shows the hot shield assembly positioned between a frame 160 and the coating drum 110. The hot shield assembly 500 can be used in place of hot shield assembly 152.

The hot shield assembly 500 includes a hot shield 501. The hot shield 501 is utilized to maintain the alkali metal in a molten phase or vapor phase during deposition of the alkali metal on the continuous flexible substrate 108. The hot shield 501 has a first pair of opposing sidewalls 501a, 501b. Sidewall 501a can be concave such that it is adaptable to the coating drum 110. During use, the sidewall 501a is positioned nearer the coating drum 110, while the sidewall 501b is positioned nearer to the frame 160 that supports an evaporation assembly (e.g., evaporation assembly 140, 200, 300).

The hot shield 501 further includes a second pair of opposing sidewalls 506a, 506b (collectively 506). A distance between the second pair of opposing sidewalls 506 is larger than, for example, the length dimension (L2) of the top surface 234b or the length dimension (L4) of the top surface 334b.

The hot shield 501 further includes a pair of members 507a, 507b (collectively 507) extending outward from and perpendicular to sidewalls 506. Members 507 also extend outward from sidewall 501b. Here, member 507a extends outward from sidewalls 501b, 506a and member 507b extends outward from sidewalls 501b, 506a. Members 507a, 507b can be welded to, bolted to, or removably attached to the hot shield 501. Alternatively, members 507a, 507b and the hot shield 501 can be machined from a single part.

Each opposing sidewall 506 is coupled to a respective plate 503a, 503b (collectively 503) of the hot shield assembly 500. The plates 503 can be made of thermally conductive material such as copper or other suitable materials. A first plurality of heaters 504a-504c (collectively 504) and a second plurality of heaters 505a-505c (collectively 505) are coupled to plate 503a and plate 503b, respectively. The hot shield 501 includes a plurality of grooves in each opposing sidewall 506 such that the heaters 504, 505 can fit within the grooves of the hot shield 501.

The hot shield assembly 500 further includes a pair of frames 502a, 502b (collectively 502). The frames 502 can be copper frames. Frame 502a is positioned on a surface of the plate 503a that is opposite from the surface of the plate 503a that is coupled to the sidewall 506a of the hot shield 501. Frame 502b is positioned on a surface of the plate 503b that is opposite from the surface of the plate 503b that is coupled to the sidewall 506b of the hot shield 501.

The hot shield assembly 500 further includes a pair of mounting mechanisms 510a, 510b (collectively 510) for mounting the hot shield 501 to the pair of frames 502a, 502b of the hot shield assembly 500 by the members 507a, 507b of the hot shield 501. The mounting mechanisms 510 can be removably secured to the members 507 by, for example, bolts 514a, 514b and washers 512a, 512b.

Relative to conventional hot shield assemblies, the mounting mechanisms 510 are flipped horizontally away (and have an increased offset) from the hot shield. Such a configuration can enable the larger hotshield described herein (adapted to fit the larger evaporator bodies described herein) to be mounted to the frames 502.

As opposed to conventional hot shields which accommodate 50 nozzles, the hot shield described herein is larger to accommodate 70 nozzles. The width of the hot shield can be wider so as to accommodate a wider evaporator. The wider hot shield also reduces radiative heat load line of sight. Further, and in contrast to conventional hot shields, the hot shield assembly 500 described herein includes plates 503 between the frames 502 and the hot shield 501. Whether or not conventional technologies have plates, there is an open space between the hot shield and the frames (e.g., frames 502) to which the hot shield is mounted, causing radiative heat loss. In contrast, embodiments of the hot shield assembly described herein are free of an open space between the hot shield and the frames.

As shown in FIG. 5C (which can be part of processing chamber 100, 150), the hot shield assembly 500 is coupled to top tray 550 that serves to confine the alkali metal during deposition. The top tray 550 is coupled to an evaporation assembly (for example, evaporation assembly 200, 300) supported by frame 160 via the top surface 234b (or top surface 334b) of the evaporator body 258 (or evaporator body 358). As described above, the top surface 234b/334b can be a nozzle assembly. As shown, nozzles 405 of the nozzle assembly traverse at least a portion of the top tray 550.

The following examples are put forth so as to provide those of ordinary skill in the art with a complete disclosure and description of how to make and use embodiments of the present disclosure, and are not intended to limit the scope of embodiments of the present disclosure. Efforts have been made to ensure accuracy with respect to numbers used but some experimental errors and deviations should be accounted for.

### Examples

Table 1 shows properties of example evaporator assemblies and comparative example evaporator assemblies. Comparative Example 1 (C.Ex. 1) is a cylindrical crucible. Comparative Example 2 (C.Ex. 2) is a conventional crucible. Example 1 (Ex. 1) is a non-limiting example of selected portions of an evaporator assembly that can be utilized at the first position (A) and the second position (B). Example 2 (Ex. 2) is a non-limiting example of selected portions of an evaporator assembly that can be utilized at the third position (C) and the fourth position (D).

TABLE 1

| | C. Ex. 1 | C. Ex. 2 | Ex. 1 | Ex. 2 |
|---|---|---|---|---|
| Crucible | 43.1 | 145 × 321 | 172 × 418 | 162 × 418 |
| opening, mm | | | | |
| Crucible | 1,459 | 46,545 | 71,896 | 67,716 |
| opening | | | | |
| area, mm² | | | | |
| Evaporator | 88,200 | 88,200 | 100,380 | 100,380 |
| opening | | | | |
| area, mm² | | | | |
| Nozzle opening | 5 | 5 | 5 | 5 |
| diameter, mm | | | | |
| Number of | 50 | 50 | 70 | 70 |
| nozzles | | | | |
| Total nozzle | 981 | 981 | 1,374 | 1,374 |
| opening area | | | | |
| based on 5 mm | | | | |
| diameter, mm² | | | | |
| Nozzle:evapo- | 1:89.8:1.48 | 1:89.8:47.39 | 1:73:52.32 | 1:73:49.28 |
| rator:crucible | | | | |
| area ratio | | | | |
| Volume | 2.8 | 2.8 | 5.1 | 4.8 |
| capacity, L | | | | |

The crucible opening for Ex. 1 and Ex. 2 refer to the dimensions W1×L1 of the opening 216 of the crucible body 214, and to the dimensions W3×L3 of the opening 316 of the crucible body 314, respectively. The crucible opening area is calculated πr², where r is 21.55 (one-half the diameter of 43.1 mm). The crucible opening areas for C.Ex. 2, Ex. 1, and Ex. 2 are calculated based on the width×length dimensions of the crucible opening.

The evaporator opening areas for Ex. 1 and Ex. 2 are calculated based on the dimensions W2×L2 of the top surface 234b of the evaporator body 258 and the dimensions W4×L4 of the top surface 334b of the evaporator body 358, respectively.

The total nozzle opening area based on 5 mm diameter is calculated based on the total number of nozzles multiplied by πr², where r is the radius of the nozzle opening (radius=2.5 mm).

The nozzle: evaporator: crucible area ratio is calculated based on the following ratio:

(Total nozzle opening area based on 5 mm diameter, mm²):((Evaporator opening area, mm²)/(Total nozzle opening area based on 5 mm diameter, mm²)):((Crucible opening area, mm²)/(Total nozzle opening area based on 5 mm diameter, mm²)).

For example, the nozzle:evaporator:crucible area ratio for C.Ex. 1 is 981:(88,200/981):(1,459/981)=1:89.8:1.48. As another example, the nozzle evaporator:crucible area ratio for Ex. 1 is 1374:(100,380/1374):(71,896/1374)=1:73:52.32. As another example, the nozzle:evaporator:crucible area ratio for Ex. 2 is 981:(100,380/1374):(67,716/1374)=1:73:49.28.

The volume capacity is the amount of alkali metal that can be placed in the crucible of the evaporator assembly. For Ex. 1 and Ex. 2, the volume capacity is the volume of the crucible body 214 up to the top surface 212b, and the volume of the crucible body 314 up to the top surface 312b.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

As is apparent from the foregoing general description and the specific aspects, while forms of the aspects have been illustrated and described, various modifications can be made without departing from the spirit and scope of the present disclosure. Accordingly, it is not intended that the present disclosure be limited thereby. Likewise, the term “comprising” is considered synonymous with the term “including.” Likewise whenever a composition, process operation, process operations, an element or a group of elements is preceded with the transitional phrase “comprising,” it is understood that we also contemplate the same composition or group of elements with transitional phrases “consisting essentially of,” “consisting of,” “selected from the group of consisting of,” or “Is” preceding the recitation of the composition, process operation, process operations, element, or elements and vice versa, such as the terms “comprising,” “consisting essentially of,” “consisting of” also include the product of the combinations of elements listed after the term.

For purposes of this present disclosure, and unless otherwise specified, all numerical values within the detailed description and the claims herein are modified by “about” or “approximately” the indicated value, and consider experimental error and variations that would be expected by a person having ordinary skill in the art. For the sake of brevity, only certain ranges are explicitly disclosed herein. However, ranges from any lower limit may be combined with any upper limit to recite a range not explicitly recited, as well as, ranges from any lower limit may be combined with any other lower limit to recite a range not explicitly recited, in the same way, ranges from any upper limit may be combined with any other upper limit to recite a range not explicitly recited. For example, the recitation of the numerical range 1 to 5 includes the subranges 1 to 4, 1.5 to 4.5, 1 to 2, among other subranges. As another example, the recitation of the numerical ranges 1 to 5, such as 2 to 4, includes the subranges 1 to 4 and 2 to 5, among other subranges. Additionally, within a range includes every point or individual value between its end points even though not explicitly recited. For example, the recitation of the numerical range 1 to 5 includes the numbers 1, 1.5, 2, 2.75, 3, 3.80, 4, 5, among other numbers. Thus, every point or individual value may serve as its own lower or upper limit combined with any other point or individual value or any other lower or upper limit, to recite a range not explicitly recited.

As used herein, the indefinite article “a” or “an” shall mean “at least one” unless specified to the contrary or the context clearly indicates otherwise. For example, aspects comprising “an evaporator assembly” includes aspects comprising one, two, or more evaporator assemblies, unless specified to the contrary or the context clearly indicates only one evaporator assembly is included.

While the foregoing is directed to aspects of the present disclosure, other and further aspects of the disclosure may be devised without departing from the basic scope thereof, and the scope thereof is determined by the claims that follow.

1. An evaporation assembly for alkali metal deposition, the evaporation assembly comprising:
a first heater region comprising a plurality of first heaters;
an evaporator body, at least a portion of the evaporator body positioned within the first heater region, wherein:
the evaporator body comprises a top surface having a plurality of linear arrays of nozzles;
a second heater region comprising one or more second heaters; and
a crucible positioned within the second heater region, the crucible comprising a crucible body fluidly coupled with the evaporator body, wherein:
the crucible body defines an interior region for holding the material to be evaporated;
the crucible body has an opening through which the evaporated material can escape; and
the crucible body has a length dimension and a width dimension defining an evaporation surface area.

2. The evaporation assembly of claim 1, wherein:
each nozzle has an opening defined by a diameter;
a total area of the openings defines a nozzle opening surface area; and
the evaporation surface area of the crucible body is greater than the nozzle opening surface area.

3. The evaporation assembly of claim 1, wherein the evaporator body further comprises a bottom surface which corresponds with the opening in the crucible body.

4. The evaporation assembly of claim 1, wherein:
the evaporator body further comprises a first pair of opposing sidewalls extending downward from the top surface, the first pair of opposing sidewalls defining a length dimension of the evaporator body;
the evaporator body further comprises a second pair of opposing sidewalls extending downward from the top surface, the second pair of opposing sidewalls defining a width dimension of the evaporator body; and
the plurality of first heaters of the first heater region extend the length dimension of the evaporator body.

5. The evaporation assembly of claim 4, wherein the first heater region further comprises:
a first conductive member positioned between a first heater of the first plurality of heaters and a first sidewall of the first pair of opposing sidewalls; and
a second conductive member positioned between a second heater of the first plurality of heaters and a second sidewall of the first pair of opposing sidewalls.

6. The evaporation assembly of claim 5, wherein a third heater of the first plurality of heaters is positioned between the first and second heaters of the first plurality of heaters.

7. The evaporation assembly of claim 1, wherein:
the plurality of first heaters are tubular heaters; and
the one or more second heaters are tubular heaters.

8. The evaporation assembly of claim 1, further comprising an alkali metal delivery line, the alkali metal delivery line comprising:
a first section positioned exterior to the evaporation assembly;
a second section positioned in an interior region of the evaporation assembly, the second section traversing the interior of the evaporator body and the crucible body;
a third section positioned in an interior region of the evaporation assembly and below the opening of the crucible body; and
a plurality of openings through which alkali metal enters the crucible.

9. The evaporation assembly of claim 1, wherein:
the crucible is free of compartments;
the evaporation assembly is free of an external heater that radiatively heats the crucible; or
combinations thereof.

10. The evaporation assembly of claim 1, further comprising a heated delivery line, the heated delivery line coupled to the interior region of the crucible body, the heated delivery line for supplying alkali metal to be deposited to the crucible body.

11. An evaporation assembly for alkali metal deposition, the evaporation assembly comprising:
a first heater region comprising a plurality of first heaters;
a second heater region comprising one or more second heaters;
an evaporator body, at least a portion of the evaporator body positioned within the first heater region and within the second heater region, wherein:
the evaporator body comprises:
a top surface having a plurality of linear arrays of nozzles;
a first pair of opposing sidewalls extending outward from the top surface, the first pair of opposing sidewalls defining a length dimension of the evaporator body; and
a second pair of opposing sidewalls extending outward from the top surface, the second pair of opposing sidewalls defining a width dimension of the evaporator body; and
the plurality of first heaters of the first heater region extend the length dimension of the evaporator body;
a third heater region comprising one or more third heaters; and
a crucible positioned within the third heater region, the crucible further positioned outside of the first heater region and the second heater region, the crucible comprising a crucible body fluidly coupled with the evaporator body, wherein:
the crucible body defines an interior region for holding the material to be evaporated;
the crucible body has an opening through which the evaporated material can escape; and
the crucible body has a length dimension and a width dimension defining an evaporation surface area; and
wherein the second heater region is positioned above the opening of the crucible body.

12. The evaporation assembly of claim 11, wherein the first heater region further comprises:
a first conductive member positioned between a first heater of the first plurality of heaters and a first sidewall of the first pair of opposing sidewalls; and
a second conductive member positioned between a second heater of the first plurality of heaters and a second sidewall of the first pair of opposing sidewalls.

13. The evaporation assembly of claim 11, wherein the one or more second heaters of the second heater region extend the length dimension of the evaporator body.

14. The evaporation assembly of claim 11, wherein:
each nozzle has an opening defined by a diameter;
a total area of the openings defines a nozzle opening surface area; and the evaporation surface area of the crucible body is greater than the nozzle opening surface area.

15. The evaporation assembly of claim 11, wherein the evaporator body further comprises:
a bottom surface which corresponds with the opening in the crucible body; and
a side surface which corresponds with a side surface of the crucible.

16. The evaporation assembly of claim 11, wherein:
the crucible is free of compartments; and
the evaporation assembly is free of an external heater that radiatively heats the crucible.

17. The evaporation assembly of claim 11, further comprising an alkali metal delivery line, the alkali metal delivery line comprising:
a first section positioned exterior to the evaporation assembly;
a second section positioned in an interior region of the evaporation assembly, the second section traversing the interior of the evaporator body and the crucible body;
a third section positioned in an interior region of the evaporation assembly and below the opening of the crucible body; and
a plurality of openings through which alkali metal enters the crucible.

18. A processing chamber for depositing alkali metal, the processing chamber comprising:
a coating drum;
a plurality of evaporation assemblies radially disposed about the coating drum, wherein:
a first evaporation assembly of the plurality of evaporation assemblies has a first angle of inclination, the first evaporation assembly comprising:
a first heater region comprising a plurality of first heaters; an evaporator body, at least a portion of the evaporator body positioned within the first heater region, wherein:
the evaporator body comprises a top surface having a plurality of linear arrays of nozzles;
a second heater region comprises one or more second heaters; and
a crucible is positioned within the second heater region, the crucible comprising a crucible body fluidly coupled with the evaporator body, wherein the crucible body defines an interior region for holding the material to be evaporated, the crucible body has an opening through which the evaporated material can escape, and the crucible body has a length dimension and a width dimension defining an evaporation surface area; and
a second evaporation assembly of the plurality of evaporation assemblies has a second angle of inclination that is different from the first angle of inclination.

19. The processing chamber of claim 18, wherein the second evaporation assembly comprises:
a first heater region comprising a plurality of first heaters;
a second heater region comprising one or more second heaters;
an evaporator body, at least a portion of the evaporator body positioned within the first heater region and within the second heater region, wherein:
the evaporator body comprises:
a top surface having a plurality of linear arrays of nozzles;
a first pair of opposing sidewalls extending outward from the top surface, the first pair of opposing sidewalls defining a length dimension of the evaporator body; and
a second pair of opposing sidewalls extending outward from the top surface, the second pair of opposing sidewalls defining a width dimension of the evaporator body; and
the plurality of first heaters of the first heater region extend the length dimension of the evaporator body;
a third heater region comprising one or more third heaters;
a crucible positioned within the third heater region, the crucible further positioned outside of the first heater region and the second heater region, the crucible comprising a crucible body fluidly coupled with the evaporator body, wherein:
the crucible body defines an interior region for holding the material to be evaporated;
the crucible body has an opening through which the evaporated material can escape; and
the crucible body has a length dimension and a width dimension defining an evaporation surface area; and
wherein the second heater region is positioned above the opening of the crucible body.

20. The processing chamber of claim 19, wherein:
the first angle of inclination is from about 20 degrees to about 25 degrees; and
the second angle of inclination is from about 65 degrees to about 70 degrees.
